(19) United States
(12) Patent Application Publication
(10) Pub. No.: US 2024/0257336 A1
(43) Pub. Date: Aug. 1, 2024

(54) WAFER VISUAL INSPECTION APPARATUS AND WAFER VISUAL INSPECTION METHOD

(71) Applicant: SUMCO Corporation, Tokyo (JP)

(72) Inventor: Tatsuya OSADA, Tokyo (JP)

(73) Assignee: SUMCO Corporation, Tokyo (JP)

(21) Appl. No.: 18/562,960

(22) PCT Filed: May 10, 2022
(86) PCT No.: PCT/JP2022/019863

§ 371 Date: Nov. 21, 2023

(30) Foreign Application Priority Data
Jun. 4, 2021 (JP) 2021-094580

(51) Int. Cl. G06T 7/00

(52) U.S. Cl. CPC G06T 7/001; G06T 2207/20021; G06T 2207/20216; G06T 2207/30148

(57) ABSTRACT

The visual inspection apparatus comprises a controller that generates a plurality of overall images of a wafer surface including part images taken by dividing the wafer surface into a plurality of areas along the circumferential direction, generates an average image based on the plurality of overall images, and detects abnormalities on the wafer surface based on the average image.

### TECHNICAL FIELD

The present disclosure relates to a wafer visual inspection apparatus and a wafer visual inspection method.

### BACKGROUND

Those conventional methods for evaluating the back surface of a wafer are known that detect polishing unevenness, blurs, scratches, and particles (see, for example, PTL 1, etc.).

### CITATION LIST

### Patent Literature

PTL 1: JP5433201 B1

### SUMMARY

### Technical Problem

Defects on the deposition surface of wafers (wafers with film) formed by depositing film on bare wafers are more difficult to detect than defects on bare wafers due to the effects of the film on the wafers. The quality of wafers with film should be improved by detecting defects on the deposition surface of wafers.

Therefore, the purpose of the present disclosure is to propose a wafer visual inspection apparatus and a wafer visual inspection method that can improve the quality of wafers with film.

### Solution to Problem

One embodiment of the present disclosure that solves the above problem is as follows.

[1] A visual inspection apparatus comprising a controller that generates a plurality of overall images of a wafer surface including part images taken by dividing the wafer surface into a plurality of areas along the circumferential direction, generates an average image based on the plurality of overall images, and detects abnormalities on the wafer surface based on the average image.
[2] The visual inspection apparatus according to above [1], wherein the controller generates each of the plurality of overall images based on the part images taken with different luminance.
[3] The visual inspection apparatus according to above [1] or [2], wherein the controller detects abnormalities on the wafer surface based on a difference image obtained by taking the difference between the average image and the overall image. The visual inspection apparatus according to above [3], wherein the [4] controller extracts pixels, in the difference image, whose luminance is equal to or greater than a first threshold value as candidate pixels for detection, and detects abnormalities on the wafer surface among the candidate pixels for detection.
[5] The visual inspection apparatus according to above [4], wherein the controller generates approximate straight lines based on positions of the candidate pixels for detection, and detects, as abnormal, the candidate pixels for detection corresponding to a combination of the approximate straight lines whose difference in slope is within a second threshold value.
[6] The visual inspection apparatus according to any one of above [1] to [5], wherein the controller detects abnormalities on the wafer surface based on the difference between an average luminance in a central area including the center of the wafer surface and an average luminance in a peripheral area other than the central area in the average image.
[7] A visual inspection method including,
generating a plurality of overall images of a wafer surface including part images taken by dividing the wafer surface into a plurality of areas along the circumferential direction,
generating an average image based on the plurality of overall images, and
detecting abnormalities on the wafer surface based on the average image.
   [8] The visual inspection method according to [7], further including generating each of the plurality of overall images based on the part images taken with different luminance.

### Advantageous Effect

According to the wafer visual inspection apparatus and the wafer visual inspection method according to the present disclosure, the quality of wafers with film can be improved.

### BRIEF DESCRIPTION OF THE DRAWINGS

In the accompanying drawings:

FIG. 1 is a block diagram illustrates a configuration example of a visual inspection system according to one embodiment;

FIG. 2 provides an example of an overall image generated based on parts image;

FIG. 3 provides an example of an average image;

FIG. 4 provides an example of a difference image;

FIG. 5 provides an example of linear approximation in the difference image;

FIG. 6 provides an example of extracting approximate straight lines with the same slope;

FIG. 7 provides an example of abnormality detection result;

FIG. 8 provides an example of film unevenness in the wafer surface;

FIG. 9 provides an example of the average image at each part from the wafer periphery to the center;

FIG. 10 provides an example of the average luminance in the average image of each part of the wafer;

FIG. 11 is a flowchart illustrating an example procedure of a visual inspection method according to one embodiment.

### DETAILED DESCRIPTION

### (Configuration Example of Wafer Visual Inspection Apparatus 10)

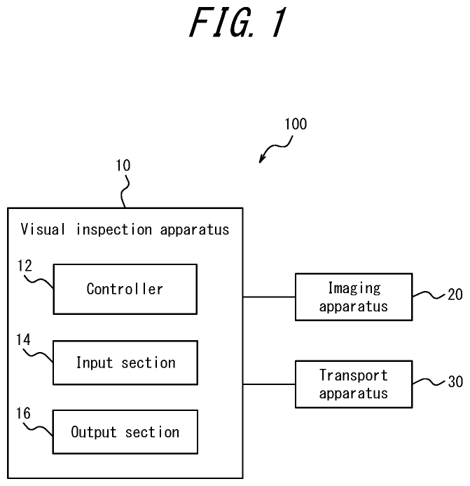

A wafer visual inspection system 100 and a visual inspection apparatus 10 according to one embodiment of the present disclosure will be described below with reference to the drawings. As illustrated in FIG. 1, a wafer visual inspection system 100 comprises a visual inspection apparatus 10, an imaging apparatus 20, and a transport apparatus 30. The imaging apparatus 20 or the transport apparatus 30 may be included in the visual inspection apparatus 10.

The visual inspection system 100 may inspect the appearance of the wafer surface, including the front or back surface of the wafer. The wafer include silicon wafers, etc. The visual inspection system 100 inspects the appearance of the wafer surface where a thin film such as a CVD (Chemical Vapor Deposition) film is formed on a polished or epitaxial wafer. The type of thin film may be an oxide film, such as a silicon oxide film, or a nitride film, such as a silicon nitride film. The type of thin film is not limited to oxide or nitride films, but may be a variety of other materials. The thickness of the thin film may be, for example, approximately 250 nm to 450 nm. The thickness of the thin film may be 250 nm or less, or may be 450 nm or more. The visual inspection system 100 that inspects the appearance of the back surface of a wafer with a thin film is described below.

The visual inspection system 100 transports a wafer to the imaging apparatus 20 by the transport apparatus 30, and the imaging apparatus 20 takes images of the front or back surface of the wafer. The imaging apparatus 20 outputs the images of the wafer taken to the visual inspection apparatus 10. The visual inspection apparatus 10 inspects the appearance of the front or back surface of the wafer based on the images of the wafer.

The visual inspection apparatus 10 comprises a controller 12, an input section 14, and an output section 16. The controller 12 controls each component of the visual inspection apparatus 10. The controller 12 obtains information or data, such as images of wafers, from the input section 14. The controller 12 outputs the results of processing based on the information or data by means of the output section 16. The controller 12 may include at least one processor. The processor may execute programs that implement the various functions of the controller 12. The processor may be realized as a single integrated circuit. The integrated circuit is also referred to as IC. The processor may be realized as a plurality of communicatively connected integrated circuits and discrete circuits. The processor may be realized based on various other known technologies.

The controller 12 may further comprise a memory section. The memory section stores, for example, images of wafers or visual inspection results based on the images of wafers. The memory section may include an electromagnetic storage medium such as a magnetic disk, or it may include a memory such as a semiconductor memory or magnetic memory. The memory section may include a non-transitory computer readable medium. The memory section stores various information and programs executed by the controller 12. The memory section may serve as the work memory for the controller 12. At least part of the memory section may be configured as a separate entity from the controller 12.

The input section 14 acquires the images of the wafer from the imaging apparatus 20 and outputs them to the controller 12. The output section 16 outputs information or data related to the results of processing in the controller 12.

The input section 14 or the output section 16 may comprise a communication device that transmits and receives information or data to and from other apparatus such as the imaging apparatus 20 or the transport apparatus 30. The communication device may be communicatively connected via a network to other apparatus. The communication device may be wired or wirelessly communicatively connected to other apparatus. The communication device may comprise a communication module that connects to a network or other apparatus. The communication module may comprise a communication interface such as LAN (Local Area Network). The communication module may comprise a communication interface for contactless communication such as infrared communication or Near Field communication (NFC). The communication module may realize communication using various communication methods, such as 4G or 5G. The communication methods implemented by the communication device are not limited to the above example and may include a variety of other methods.

The input section 14 may comprise an input device that accepts input of information or data from the user. The input device may be configured including, for example, a touch panel or touch sensor, or a pointing device such as a mouse. The input device may be configured including physical keys. The input device may be configured including an audio input device such as a microphone.

The output section 16 may include, for example, a display device that outputs images or visual information such as text or graphics. The display device may be configured including, for example, a Liquid Crystal Display (LCD), an Electro-Luminescence (EL) or inorganic EL display, or a Plasma Display Panel (PDP). The display device is not limited to these displays and may be configured including a variety of other display methods. The display device may be configured including a light emitting device such as a Light Emitting Diode (LED) or Laser Diode (LD). The display device may be configured including a variety of other devices. The output section 16 may include a speaker or other audio output device.

The imaging apparatus 20 is configured including, for example, a camera or an image sensor, etc. The imaging apparatus 20 takes images of the wafer surface, including the front or back surface of the wafer. The imaging apparatus 20 may comprise a light source that emits illumination light to illuminate the wafer surface. The imaging apparatus 20 may comprise, for example, LEDs or halogen lamps, etc. as light sources. In this embodiment, the light source is assumed to be an LED. The light source is configured to change the illuminance of the illumination light in at least two levels. The light source may be configured to change the power input. The light source may be configured to change the wavelength or spectrum of the illumination light. The light source may be configured including a plurality of light emitting devices.

The imaging apparatus 20 takes images of the wafer surface by dividing the wafer surface into a plurality of areas along each of the radial and circumferential directions of the wafer. The imaging apparatus 20 is assumed to be configured as a plurality of cameras or image sensors aligned in the radial direction of the wafer. The imaging apparatus 20 may comprise a stage on which the wafer is placed. The imaging apparatus 20 may rotate the placed wafer by rotating the stage. The imaging apparatus 20 may take images of the rotating wafer from fixed cameras or image sensors, thereby taking images of the wafer surface divided into a plurality of areas along the circumferential direction of the wafer. The imaging apparatus 20 may move the camera or image sensor with respect to the wafer placed on the stage along the circumference of the wafer, thereby taking images of the wafer surface divided into a plurality of areas along the circumferential direction of the wafer. Each area may overlap in part along the radial or circumferential direction. The images taken for each area is also referred to as part images. The imaging apparatus 20 outputs the part images to the visual inspection apparatus 10. The imaging apparatus 20 outputs information identifying the positional relationship within the wafer surface where the part image was captured to the visual inspection apparatus 10, in association with the part image.

The transport apparatus 30 transports the wafer to the imaging apparatus 20. The transport apparatus 30 may transport the wafer onto the stage of the imaging apparatus 20. The transport apparatus 30 may remove the wafer from the imaging apparatus 20 after the imaging apparatus 20 has completed taking images. The transport apparatus 30 may comprise an arm that is moved by a motor or other driving device. The transport apparatus 30 may comprise a hand or adsorption part or the like to hold the wafer.

### (Operation Example of Visual Inspection System 100)

In the visual inspection system 100, the imaging apparatus 20 takes part images of the wafer surface. In this embodiment, the imaging apparatus 20 changes the illuminance of the illumination light to three different levels and takes part images at each illuminance. The number of illuminance levels may be 2, or 4 or more. In other words, the imaging apparatus 20 changes the illuminance of the illumination light to a plurality of levels and takes part images at each illuminance. The imaging apparatus 20 generates part images of the wafer surface illuminated by the illumination light of each illuminance, by varying the illuminance of the illumination light. When the imaging apparatus 20 changes the illuminance of the illumination light in three levels, it generates three types of part images. As the illuminance of the illumination light is changed, the luminances of the part images corresponding to each illuminance are different from each other.

The illuminance of the illumination light can be set based on the type or thickness of the thin film being deposited on the wafer surface. The illuminance of the illumination light may be set between 100,000 lux and 500,000 lux, for example. The illuminance of the illumination light may be set to less than 100,000 lux or more than 500,000 lux. The illuminance of the illumination light may be set as the power input to the light source. The power input to the light source may be set between 100 watts (W) and 500 watts (W), for example. The power input to the light source may be set at less than 100 watts or more than 500 watts.

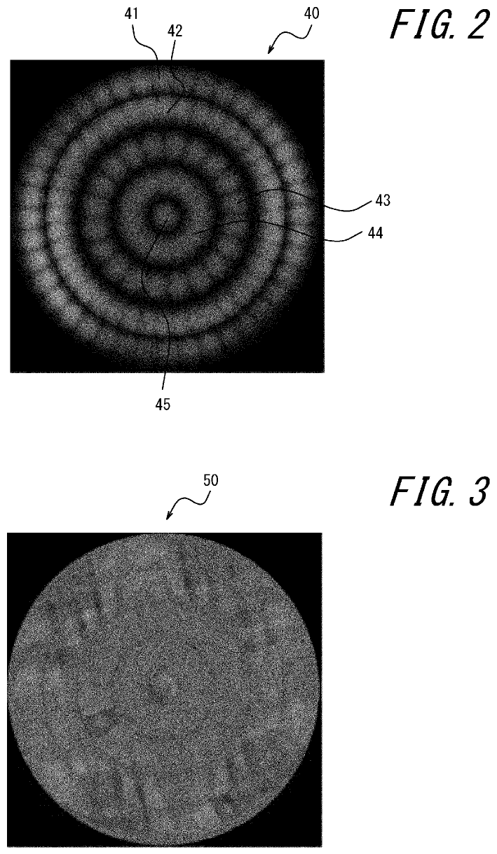

The controller 12 of the visual inspection apparatus 10 obtains, from the input section 14, the part images of the wafer surface illuminated by the illumination light of each illuminance by the imaging apparatus 20. The controller 12 generates an overall image 40 that appears to take the entire wafer surface, for example, as provided in FIG. 2, by arranging the obtained part images at each taken position based on the information identifying the positions in the wafer surface where the part images were taken. The controller 12 generates the overall image 40 for each illuminance. If the part images are taken at three different illuminances, the controller 12 generates one overall image 40 for each illuminance. That is, the controller 12 generates three overall images 40.

The controller 12 may obtain, from the input section 14, part images of the wafer surface illuminated by different wavelengths or spectra of illumination light by the imaging apparatus 20. The controller 12 may generate the overall image 40 for each wavelength or spectrum.

In FIG. 2, the part images include a first part image 41, a second part image 42, a third part image 43, a fourth part image 44, and a fifth part image 45. The first part image 41 corresponds to an image of the outermost area of the wafer surface divided into a plurality of areas along the circumferential direction. The second part image 42, the third part image 43, and the fourth part image 44 correspond to images of the second, third and fourth inner circumference from the outermost area of the wafer surface divided into a plurality of areas along the circumferential direction, respectively. The fifth part image 45 corresponds to an image of the area located in the center of the wafer surface.

The controller 12 may remove the image of particles in each part image when generating the overall image 40. The particle is a generic term for foreign particles adhering to the wafer surface.

If there are areas between each part image comprising the overall image 40 where the wafer surface is not taken, the controller 12 may interpolate the images between each part image. The controller 12 may interpolate the image using an algorithm that interpolates missing portions of the image. The algorithm for interpolating missing portions of the image may include various algorithms, for example, algorithms using neural networks.

The controller 12 generates the average image 50 provided in FIG. 3 based on the plurality of overall images 40. Specifically, the controller 12 performs differential processing on each of the plurality of overall images 40 to generate a plurality of differential images. The controller 12 may perform the differentiation processing using a filter, such as a primary differential filter, for example. The controller 12 overlays the plurality of differential images to produce the average image 50. In other words, the controller 12 can generate the average image 50 by performing differential processing on the overall images 40 of different luminances and superimposing them. The objects to be extracted by the visual inspection system 100 can be highlighted by overlaying the overall images 40 of different luminances. Also, the object to be extracted by the visual inspection system 100 can be highlighted by performing the differential processing. Conversely, the imaging apparatus 20 may set the illuminance of the illumination light so that the object to be extracted by visual inspection system 100 is highlighted. The controller 12 may select the algorithm for the differentiation processing so that the objects to be extracted by the visual inspection system 100 are highlighted.

The controller 12 may perform the differential or superimposition processing on the overall images 40 generated for each wavelength or spectrum to generate the average image 50.

The controller 12 can detect a thread-like abnormality based on the average image 50. The thread-like abnormality is also referred to as the first abnormality. Also, the controller 12 can detect a film unevenness abnormality on the wafer surface based on the average image 50. The film unevenness abnormality is also referred to as the second abnormality. Assume that the controller 12 can operate in the mode to detect the thread-like abnormality (first abnormality) and the film unevenness abnormality (second abnormality), respectively. The mode for detecting the thread-like abnormality (first abnormality) is also called the first mode. The mode for detecting the film unevenness abnormality (second abnormality) is also referred to as the second mode. The operation of each of the first and second modes is described below.

### <Operation Example in First Mode>

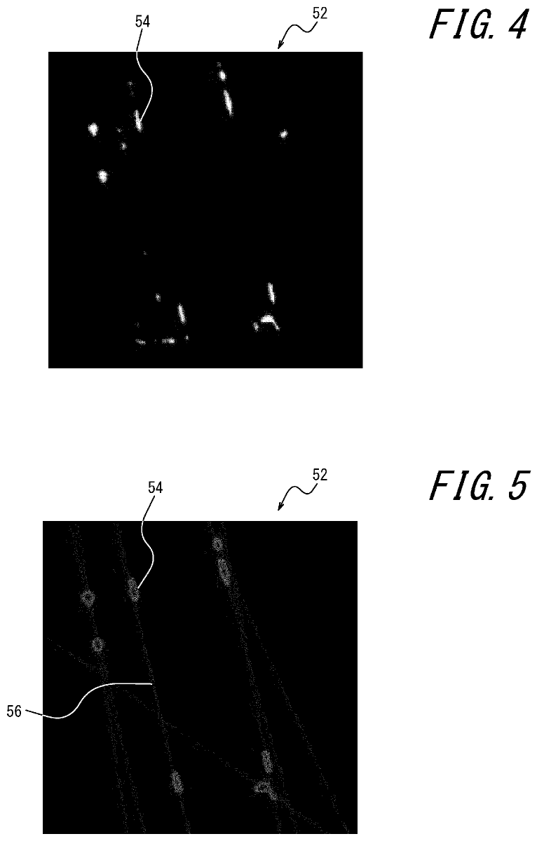

When operating in the first mode, the controller 12 generates the difference image 52 provided in FIG. 4 as the image of the difference between the overall image 40 and the average image 50. The controller 12 may take the difference between each of the plurality of overall images 40 with different luminances and the average image 50. The controller 12 may take the difference between the overall image 40 in at least one luminance and the average image 50. The difference image 52 provided in FIG. 4 is a further binarized difference between the overall image 40 and the average image 50. In the difference image 52, pixels with high luminance (represented by white) are also referred to as candidate pixels for detection 54. The controller 12 may extract the pixels that are white by the binarization process as the candidate pixels for detection 54. The controller 12 may extract the pixels in the difference image 52 whose luminance is equal to or greater than a predetermined value as the candidate pixels for detection 54. The predetermined value that serves as the basis for extracting the candidate pixels for detection 54 is also referred to as the first threshold value. The controller 12 may binarize the difference image 52 based on the first threshold value. For example, the controller 12 may perform binarization, where the pixels with luminance equal to or above the first threshold are white and the pixels with luminance below the first threshold are black.

The controller 12 extracts the candidate pixels for detection 54 in the difference image 52, as illustrated in FIG. 5. In FIG. 5, the set of candidate pixels for detection 54 is represented with the contour highlighted. The controller 12 approximates the figure represented by the set of candidate pixels for detection 54 by a straight line. For example, the controller 12 detects the longitudinal direction of the candidate pixels for detection 54 and extracts a straight line along the longitudinal direction as an approximate straight line 56. This process is also referred to as the linear approximation process.

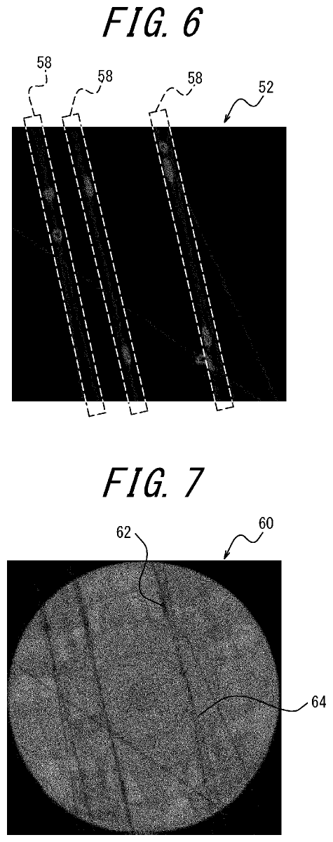

As illustrated in FIG. 6, the controller 12 extracts, among the approximate straight lines 56, a combination of approximate straight lines 56 whose slopes are the same or whose slope differences are equal to or less than a predetermined value. This process is also referred to as the same-slope extraction process. The predetermined value that serves as the basis for extracting the combination of the approximate straight lines 56 is also referred to as the second threshold value. The combination of the extracted approximate straight lines 56 is represented by a dashed rectangle and is also referred to as the extracted straight line 58.

The controller 12 may consider the extracted straight line 58 as a thread-like abnormality. When the controller 12 detects the extracted straight line 58, it may output information to the output section 16 indicating that the thread-like abnormality has been detected and notify the user. The controller 12 may also detect the candidate pixels for detection 54 corresponding to the extracted straight line 58 as abnormal.

The controller 12 may generate a result image 60, as illustrated in FIG. 7, in which the candidate pixels for detection 54 highlighted by the difference image 52 (see FIG. 4 or FIG. 5) and the approximate straight line 56 generated based on the candidate pixels for detection 54 (see FIG. 5) are superimposed on the average image 50. In the result image 60, the controller 12 may highlight the candidate pixels for detection 54 corresponding to the extracted straight line 58 extracted in FIG. 6 as detected pixels 62. Also, the controller 12 may also highlight the extracted straight line 58 as the detected straight line 64 in the result image 60. The controller 12 may notify the user of the results of the visual inspection by displaying the result image 60 on the output section 16.

The controller 12 may display the overall image 40 or the average image 50 on the output section 16.

### <Operation Example in Second Mode>

When operating in the second mode, the controller 12 can detect a film unevenness abnormality (second abnormality) based on the luminance of the average image 50.

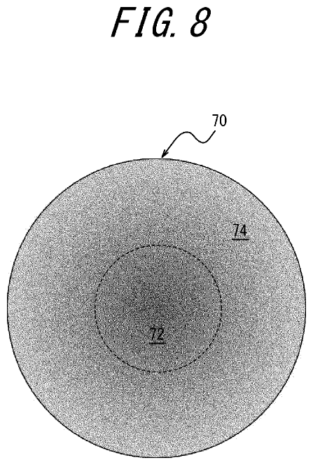

FIG. 8 provides an example of film unevenness in the wafer surface. The average image 50 of the wafer surface with a film unevenness is represented as the film unevenness image 70. In the film unevenness image 70, the luminance of the central area 72 near the center of the wafer surface is low. In other words, the central area 72 is represented by a color close to black. In addition, the luminance of the peripheral area 74 near the edge of the wafer surface is high. In other words, the peripheral area 74 is represented by a color close to white.

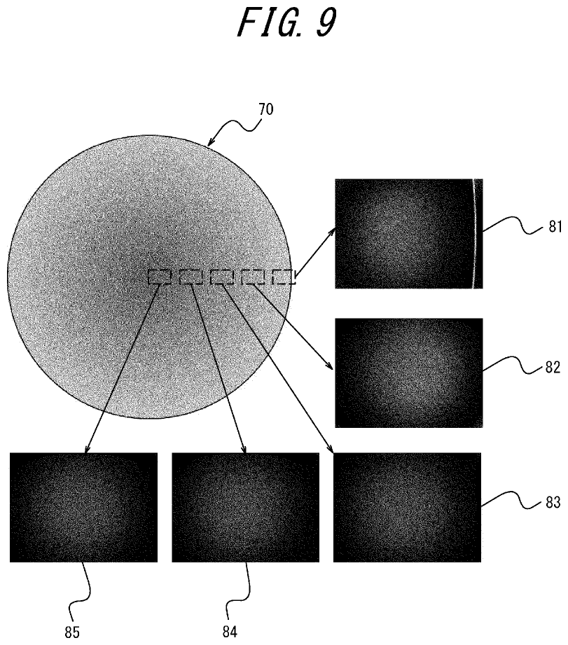

In the average image 50, the controller 12 generates an image by averaging the luminance of pixels at positions corresponding to the respective part images from the first part image 41 to the fifth part image 45 in FIG. 2. For example, as provided in FIG. 9, the images averaging the luminances of the positions corresponding to the respective part images from the first part image 41 to the fifth part image 45 are represented as the first luminance average image 81 to the fifth luminance average image 85. In this embodiment, the controller 12 classified the images for which the luminance average image is calculated into five groups, however it may also classify them into four or fewer groups or into six or more groups.

The controller 12 calculates the average luminance of each image from the first luminance average image 81 to the fifth luminance average image 85. The controller 12 normalizes the average luminance. In this embodiment, the controller 12 normalized the average luminance of the other images by setting the average luminance of the second luminance average image 82 as 100%, assuming that the average luminance of the second luminance average image 82 is unlikely to vary from wafer to wafer. The reference image for normalization is not limited to the second luminance average image 82, but may be any other images such as the first luminance average image 81, the third luminance average image 83, the fourth luminance average image 84, or the fifth luminance average image 85. The average luminance which was normalized is also referred to as the normalized average luminance. When the normalized average luminance is below the decision threshold, the controller 12 determines that the film unevenness abnormality has occurred on the wafer.

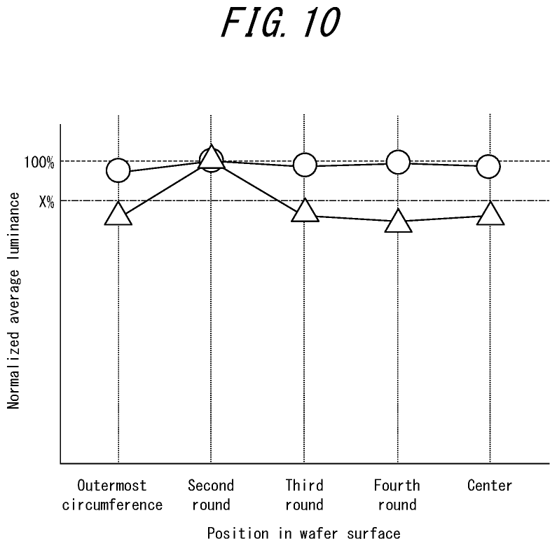

An example of the calculation results of the normalized average luminance is provided as a graph in FIG. 10. The horizontal axis of the graph in FIG. 10 represents the position in the wafer surface. The “Outermost circumference” represents the position corresponding to the first part image 41. The “Second round” represents the position corresponding to the second part image 42. The “Third round” represents the position corresponding to the third part image 43. The “Fourth round” represents the position corresponding to the fourth part image 44. The “Center” represents the position corresponding to the fifth part image 45. The vertical axis represents the normalized average luminance calculated based on the luminance average images at each position.

Assuming that the decision threshold is expressed as X %. The graph in which the normalized average luminance at each position is represented by a circle indicates that the normalized average luminance is equal to or greater than X % at all positions. In this case, the controller 12 determines that the film unevenness abnormality does not occur in the wafer corresponding to the graph in which the normalized average luminance is represented by a circle. On the other hand, the graph in which the normalized average luminance at each position is represented by a triangle indicates that the normalized average luminance is less than X % at some positions. In this case, the controller 12 determines that the film unevenness abnormality has occurred in the wafer corresponding to the graph in which the normalized average luminance is represented by a triangle. In other words, the controller 12 can compare the normalized average luminance with the decision threshold to determine if the film unevenness abnormality has occurred. The decision threshold may be set to various values, such as 80% or 90%, for example.

### (Procedures Example of Visual Inspection Method)

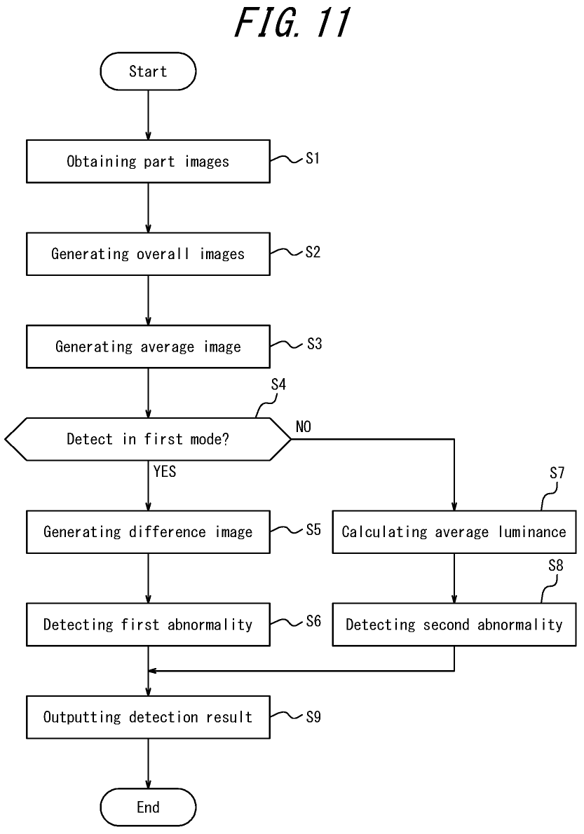

The controller 12 of the visual inspection apparatus 10 may execute a visual inspection method including the flowchart procedure illustrated in FIG. 11. The visual inspection method may be realized as a visual inspection program to be executed by a processor comprising the controller 12. The visual inspection program may be stored on a non-transitory computer readable medium.

The controller 12 obtains the part images (step S1). The controller 12 generates the overall images 40 based on the part images (step S2). The controller 12 generates an average image 50 based on the overall images 40 (step S3). The controller 12 determines whether to detect in the first mode (step S4). If the controller 12 detects in the first mode (step S4: YES), it proceeds to step S5. If the controller 12 does not detect in the first mode (step S4: NO), it proceeds to step S7.

When detecting in the first mode, the controller 12 generates a difference image 52 by taking the difference between the overall image 40 and the average image 50 (step S5). The controller 12 detects the first abnormality (thread-like abnormality) based on the difference image 52 (step S6). Specifically, the controller 12 may perform the binarization process, or the linear approximation process and the same-slope extraction process in the procedure of step S6. After performing the procedure in step S6, the controller 12 proceeds to the procedure in step S9.

When detecting in the second mode, the controller 12 calculates the average luminance at each position in the wafer surface (step S7). The controller 12 detects the second abnormality (film unevenness abnormality) based on the calculated average luminance (step S8). After performing the procedure in step S8, the controller 12 proceeds to the procedure in step S9.

The controller 12 outputs the detection result in the first or second mode (step S9). After executing the procedure in step S9, the controller 12 terminates the execution of the procedure in the flowchart in FIG. 11. The controller 12 may perform both detection of the first mode and the second mode. The controller 12 may perform the detection of the first mode first, the detection of the second mode first, or the detection of the first and second modes in parallel.

As described above, according to the visual inspection system 100, the visual inspection apparatus 10, and the visual inspection method according to this embodiment, the image highlighting abnormalities on the wafer surface of a wafer with a film can be generated. As a result, the quality of the wafer with film can be improved.

Although the embodiments according to the present disclosure have been described based on the drawings and examples, it should be noted that one skilled in the art can make various changes or modifications based on the present disclosure. Therefore, it should be noted that these various changes or modifications are included within the scope of this disclosure. For example, the functions included in each component or steps can be rearranged in a logically consistent manner, and multiple components or steps can be combined or divided into one. Although the embodiments according to the present disclosure have been described with a focus on the apparatus, the embodiments according to the present disclosure can also be realized as a method that includes steps executed by each component of the apparatus. The embodiments according to the present disclosure can also be realized as a method executed by a processor provided with the apparatus, a program, or a storage medium recording the program. It should be understood that the scope of this disclosure includes these as well.

The graph included in this disclosure is schematic. The scales, etc., do not necessarily correspond to reality.

### INDUSTRIAL APPLICABILITY

According to the embodiments of the present disclosure, the quality of wafers with film can be improved.

### REFERENCE SIGNS LIST

100 Visual inspection system
10 Visual inspection apparatus (12: Controller, 14: Input section, 16: Output section)
20 Imaging apparatus
30 Transport apparatus
40 Overall image (41 to 45: First to fifth part images)
50 Average image
52 Difference image (54: Candidate pixels for detection, 56: Approximate straight line, 58: Extracted straight line)
60 Result image (62: Detected pixels, 64: Detected straight line)
70 Film unevenness image (72: Central area, 74: Peripheral area)
81-85 First to fifth luminance average images

1. A visual inspection apparatus comprising a controller that generates a plurality of overall images of a wafer surface including part images taken by dividing the wafer surface into a plurality of areas along the circumferential direction, generates an average image based on the plurality of overall images, and detects abnormalities on the wafer surface based on the average image.

2. The visual inspection apparatus according to claim 1, wherein the controller generates each of the plurality of overall images based on the part images taken with different luminance.

3. The visual inspection apparatus according to claim 1, wherein the controller detects abnormalities on the wafer surface based on a difference image obtained by taking the difference between the average image and the overall image.

4. The visual inspection apparatus according to claim 3, wherein the controller extracts pixels, in the difference image, whose luminance is equal to or greater than a first threshold value as candidate pixels for detection, and detects abnormalities on the wafer surface among the candidate pixels for detection.

5. The visual inspection apparatus according to claim 4, wherein the controller generates approximate straight lines based on positions of the candidate pixels for detection, and detects, as abnormal, the candidate pixels for detection corresponding to a combination of the approximate straight lines whose difference in slope is within a second threshold value.

6. The visual inspection apparatus according to claim 1, wherein the controller detects abnormalities on the wafer surface based on the difference between an average luminance in a central area including the center of the wafer surface and an average luminance in a peripheral area other than the central area in the average image.

7. A visual inspection method including,
generating a plurality of overall images of a wafer surface including part images taken by dividing the wafer surface into a plurality of areas along the circumferential direction,
generating an average image based on the plurality of overall images, and
detecting abnormalities on the wafer surface based on the average image.

8. The visual inspection method according to claim 7, further including generating each of the plurality of overall images based on the part images taken with different luminance.

9. The visual inspection apparatus according to claim 2, wherein the controller detects abnormalities on the wafer surface based on a difference image obtained by taking the difference between the average image and the overall image.

10. The visual inspection apparatus according to claim 9, wherein the controller extracts pixels, in the difference image, whose luminance is equal to or greater than a first threshold value as candidate pixels for detection, and detects abnormalities on the wafer surface among the candidate pixels for detection.

11. The visual inspection apparatus according to claim 10, wherein the controller generates approximate straight lines based on positions of the candidate pixels for detection, and detects, as abnormal, the candidate pixels for detection corresponding to a combination of the approximate straight lines whose difference in slope is within a second threshold value.

12. The visual inspection apparatus according to claim 2, wherein the controller detects abnormalities on the wafer surface based on the difference between an average luminance in a central area including the center of the wafer surface and an average luminance in a peripheral area other than the central area in the average image.

13. The visual inspection apparatus according to claim 3, wherein the controller detects abnormalities on the wafer surface based on the difference between an average luminance in a central area including the center of the wafer surface and an average luminance in a peripheral area other than the central area in the average image.

14. The visual inspection apparatus according to claim 4, wherein the controller detects abnormalities on the wafer surface based on the difference between an average luminance in a central area including the center of the wafer surface and an average luminance in a peripheral area other than the central area in the average image.

15. The visual inspection apparatus according to claim 5, wherein the controller detects abnormalities on the wafer surface based on the difference between an average luminance in a central area including the center of the wafer surface and an average luminance in a peripheral area other than the central area in the average image.

16. The visual inspection apparatus according to claim 9, wherein the controller detects abnormalities on the wafer surface based on the difference between an average luminance in a central area including the center of the wafer surface and an average luminance in a peripheral area other than the central area in the average image.

17. The visual inspection apparatus according to claim 10, wherein the controller detects abnormalities on the wafer surface based on the difference between an average luminance in a central area including the center of the wafer surface and an average luminance in a peripheral area other than the central area in the average image.

18. The visual inspection apparatus according to claim 11, wherein the controller detects abnormalities on the wafer surface based on the difference between an average luminance in a central area including the center of the wafer surface and an average luminance in a peripheral area other than the central area in the average image.
